(19) United States
(12) Patent Application Publication
(10) Pub. No.: US 2025/0309191 A1
(43) Pub. Date: Oct. 2, 2025

(54) METHOD FOR FABRICATING SEMICONDUCTOR DEVICE

(71) Applicant: UNITED MICROELECTRONICS CORP., Hsin-Chu City (TW)

(72) Inventors: Chuan-Lan Lin, Chiayi City (TW); Chu-Fu Lin, Kaohsiung City (TW)

(73) Assignee: UNITED MICROELECTRONICS CORP., Hsin-Chu City (TW)

(21) Appl. No.: 18/660,207

(22) Filed: May 9, 2024

(30) Foreign Application Priority Data
Mar. 29, 2024 (TW) 113111909

(51) Int. Cl. H01L 23/00; H01L 21/66

(52) U.S. Cl. CPC H01L 24/94; H01L 22/14; H01L 24/82; H01L 24/83; H01L 24/98; H01L 2224/82948; H01L 2224/83005; H01L 2224/94; H01L 2224/98; H01L 2924/3511

(57) ABSTRACT

A method for fabricating semiconductor device includes the steps of: providing a first wafer and a second wafer, bonding the first wafer onto a carrier by forming an adhesive layer between the carrier and the first wafer, conducting a front end of line (FEOL) process and a back end of line (BEOL) process on the first wafer and the second wafer, forming direct bond interconnects (DBI) on the first wafer and the second wafer, bonding the first wafer and the second wafer, and performing a de-bonding process to detach the carrier and the first wafer.

### BACKGROUND OF THE INVENTION

### 1. Field of the Invention

The invention relates to a method for fabricating semiconductor device, and more particularly to a method of first bonding a first wafer to a carrier and then connecting to a second wafer.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

Today, techniques combining through-silicon vias (TSVs) and redistribution layers (RDLs) have often been used for achieving wafer to wafer stacking, in which the through-silicon via technique drills holes in the wafer by etching or laser then fills the holes with conductive materials, such as copper, polysilicon or tungsten to form vias, i.e. conductive channels connecting inner regions and outer regions. The wafer or the dice is then thinned to be stacked or bonded together to form a 3D stack IC. Nevertheless, processes involving TSVs and RDLs often affect yield and increase overall fabrication cost. Hence, how to improve current wafer to wafer stacking process has become an important task in this field.

### SUMMARY OF THE INVENTION

According to an embodiment of the present invention, a method for fabricating semiconductor device includes the steps of: providing a first wafer and a second wafer, bonding the first wafer onto a carrier by forming an adhesive layer between the carrier and the first wafer, conducting a front end of line (FEOL) process and a back end of line (BEOL) process on the first wafer and the second wafer, forming direct bond interconnects (DBI) on the first wafer and the second wafer, bonding the first wafer and the second wafer, and performing a de-bonding process to detach the carrier and the first wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

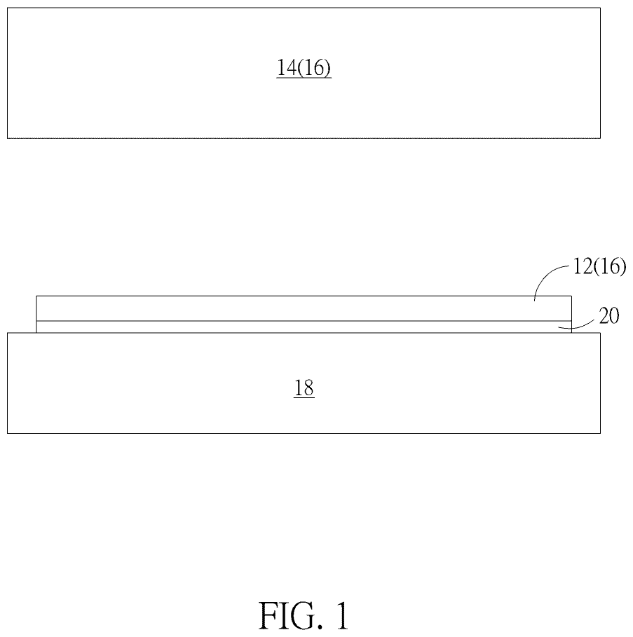

Referring to FIGS. 1-6, FIGS. 1-6 illustrate a method for fabricating a semiconductor device according to an embodiment of the present invention. As shown in FIG. 1, a wafer 12 and a wafer 14 both made of semiconductor material is provided. Preferably, each of the wafers 12, 14 include a substrate 16 made of semiconductor materials as the substrate 12 could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, each of the wafers 12, 14 could be used for fabricating elements including MV devices, HV devices, pixel circuits, LV devices for LV driving circuits, and/or graphics process unit (GPU).

It should be noted at this stage, each of the wafers 12, 14 only includes a blanket wafer made of silicon substrate. In other words, each of the wafers 12, 14 only includes a substrate 16 made of silicon that has never been processed through any semiconductor fabrication process as no elements such as semiconductor patterns or metal-oxide semiconductor (MOS) transistors fabricated through semiconductor process are formed on the substrate 12.

Next, a thinning process could be conducted to lower the overall thickness of the wafer 12 while no thinning process is conducted on the wafer 14 as the wafer 14 maintains its original thickness. According to a preferred embodiment of the present invention, the thickness of the thinned wafer 12 is less than 1/10 of the thickness of the wafer 14. For instance, the thickness of the wafer 12 is less than 5 microns while the thickness of the wafer 14 is between 700-850 microns or most preferably 775 microns. According to other embodiment of the present invention, the wafers 12 and 14 could also have different thicknesses but same width, which is also within the scope of the present invention.

Next, the wafer 12 is bonded to a carrier 18 by forming an adhesive layer 20 between the carrier 18 and the wafer 12. In this embodiment, the carrier 18 and the adhesive layer 20 are temporary holding or carrying elements provided for transporting the wafer 12, in which both the carrier 18 and the adhesive layer 20 could withstand high temperature as very low coefficient of thermal expansion (CTE) mismatch is achieved between the carrier 18 and/or adhesive layer 20 and the wafer 12 made of silicon. In other words, warpage is unlikely to occur among the carrier 18, the adhesive layer 20, and the wafer 12 as a result of difference in CTE mismatch. In this embodiment, the carrier 18 and the wafers 12, 14 could be made of same or different materials. For instance, the carrier 18 could be made of material such as silicon, silicon carbide (SiC), and/or glass.

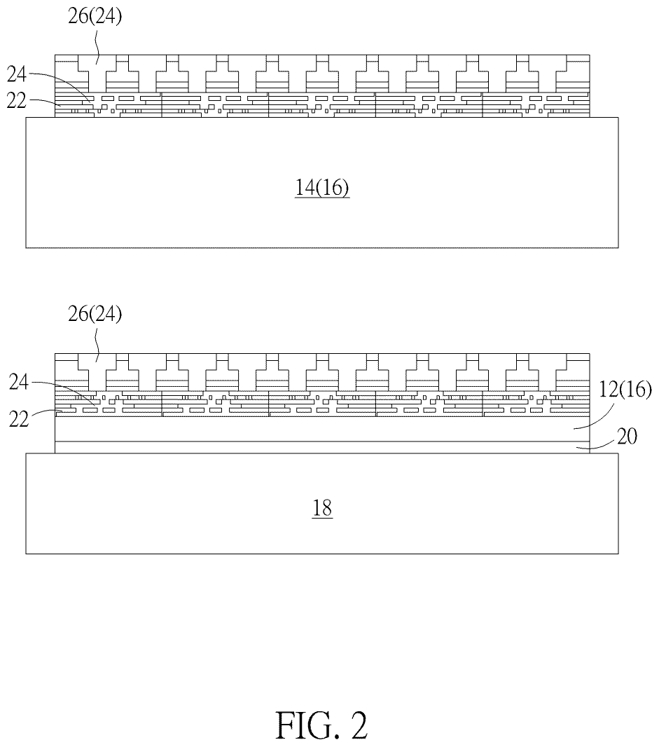

Next, as shown in FIG. 2, a front end of line (FEOL) and a back end of line (BEOL) fabrication processes could be conducted on the wafers 12, 14 respectively while the wafer 12 is adhered onto the carrier 18. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers 22 and metal interconnections 24 on the aforementioned active devices and/or passive devices.

If a MOS transistor were to be fabricated, the FEOL process could include the steps of forming a gate structure on the substrate 16, forming a spacer (not shown) adjacent to sidewalls of the gate structure and a source/drain region in the substrate adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 16 to cover the MOS transistor or other active devices, and then a contact plug formation and metal interconnect process from BEOL process could be conducted to form a plurality of contact plugs in the ILD layer for connecting the source/drain region and the gate structure, an IMD layer 22 disposed on the ILD layer, and metal interconnections 24 in the IMD layer 22 for connecting the contact plugs, in which the topmost metal interconnection 24 on front side of the wafers 12, 14 could be used as connecting junctions such as direct bond interconnects (DBIs) 26 as the two wafers could be bonded through DBIs 26 in the later process. In this embodiment, the ILD layer and the IMD layer 22 could include oxides including but not limited to for example tetraethyl orthosilicate (TEOS) and the contact plugs, the metal interconnections 24, and the DBIs 26 could include Al, Cr, Cu, Ta, Mo, W, or combination thereof.

It should be noted that even though a thinning process is first conducted to thin the wafer 12 and then bond the thinned wafer 12 onto the carrier 18 afterwards for carrying out FEOL and BEOL processes in this embodiment, according to other embodiment of the present invention it would also be desirable to skip the thinning process by directly providing a substantially thinner wafer 12 and a substantially thicker wafer 14, bonding the wafer 12 onto the carrier 18, and then performing FEOL and BEOL process on the wafers 12 and 14 respectively, which is also within the scope of the present invention.

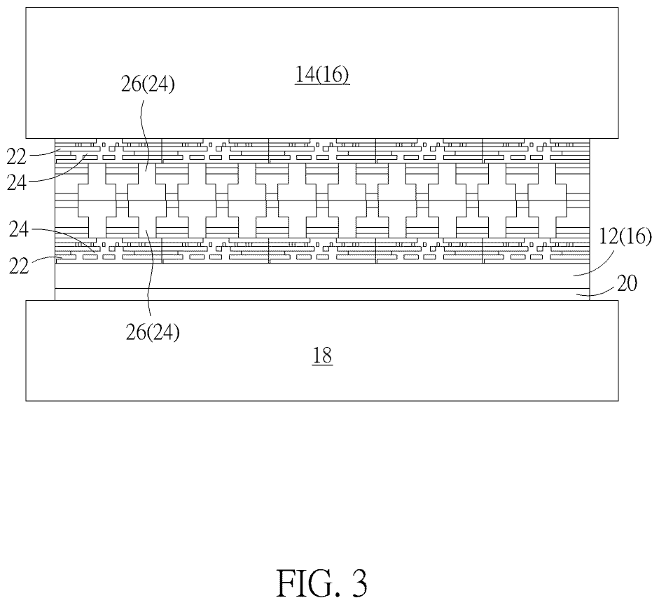

Next, as shown in FIG. 3, a hybrid bonding process is conducted by using the DBIs to connect the wafer 12 and the wafer 14. Preferably, the bonding process could be accomplished by first reversing the wafer 14 so that the front side of the wafer 14 or the exposed surface of the DBIs 26 is facing toward the front side of the wafer 12 or the exposed surface of the DBIs 26, and then performing a thermal treatment process to directly bond the two wafers 12, 14 by directly contacting the DBIs 26 on both wafers 12, 14 so that DBIs 26 and IMD layer 22 on the wafer 14 directly contacting the DBIs 26 and IMD layer 22 on the wafer 12.

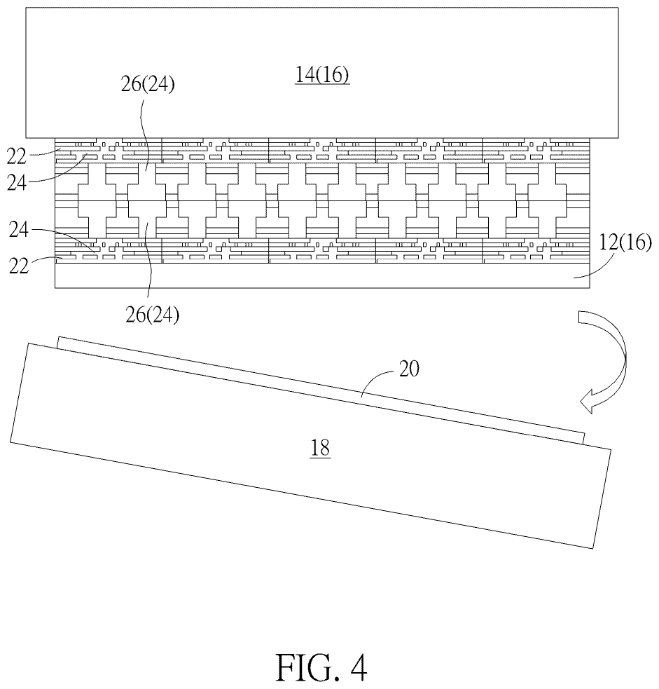

Next, as shown in FIG. 4, after the two wafers 12 and 14 are bonded through hybrid bonding process by connecting uppermost metal interconnections 24 on each wafer, a de-bonding process could be conducted by using laser or solution immersion for separating the carrier 18 and the wafer 12. At this stage, the carrier 18 is detached from the bottom surface of the wafer 12 and the bottom or backside of the wafer 12 is exposed while the two wafers 12 and 14 are still connected to each other.

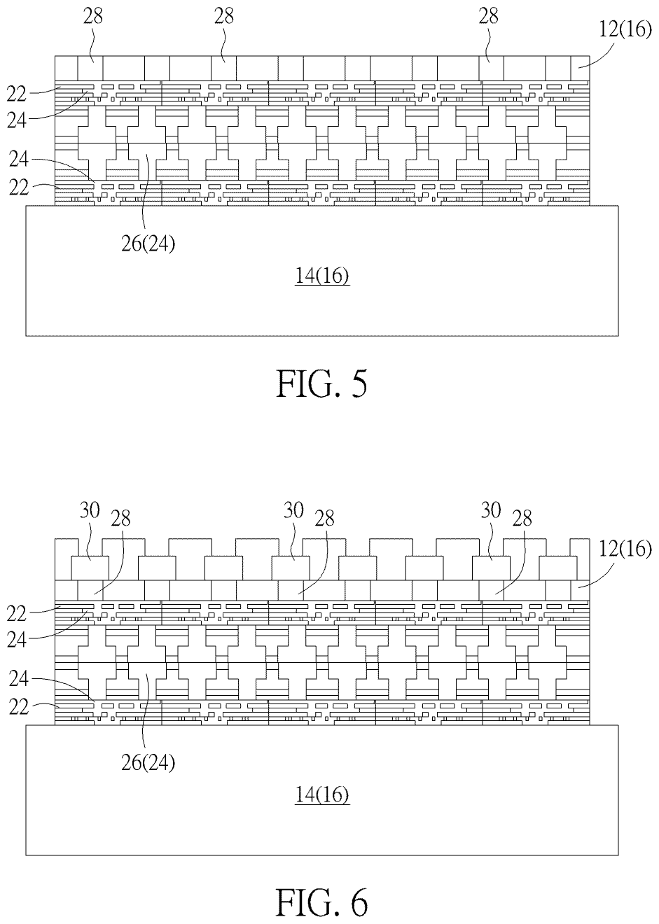

Next, as shown in FIG. 5, the combined stack structure of the two wafers 12, 14 could be reversed so that the backside of the wafer 12 is facing upward, and then metal interconnections 28 such as first level metal interconnections M1 could be formed in the substrate 16 on backside of the wafer 12. Specifically, the formation of the metal interconnections 28 could be accomplished by first conducting a photo-etching process to remove part of the substrate 16 for forming contact holes and then filling conductive material such as copper into the contact holes through electroplating process along with a planarizing process such as chemical mechanical polishing (CMP) process for forming metal interconnections 28 in the substrate 16. Preferably, the top surface of the planarized metal interconnections 28 is even with the surface of the substrate 16.

Next, as shown in FIG. 6, additional layers such as second level or third level metal interconnections (not shown) could be formed on top of the first level metal interconnections 28 depending on the demand of the process and bonding pads 30 are formed on the topmost level metal interconnection thereafter. Material wise, each of the bonding pads 30 could further includes a barrier layer and a metal layer, in which the barrier layer could be selected from the group consisting of titanium (Ti), titanium nitride (TiN), tantalum (Ta), and tantalum nitride (TaN) and metal layer could be selected from the group consisting of tungsten (W), copper (Cu), aluminum (Al), titanium aluminide (TiAl), and cobalt tungsten phosphide (CoWP), but not limited thereto.

Next, a chip probing test could be conducted through the bonding pads 30. Typically, the fabrication process conducted in FIGS. 1-6 are carried out either in a fab or outsourced semiconductor assembly and test (OSAT) facilities. For instance, process including forming active devices and bonding pads on the wafer 12 is usually completed in a fab while separating the wafers 12, 14 into a plurality of dies or chips after conducting the chip probing test is typically accomplished in OSAT facilities. This completes the fabrication of a semiconductor device according to an embodiment of the present invention.

Overall, the present invention first provides a first wafer such as wafer 12 and a second wafer such as wafer 14, thins the first wafer, bonds the thinned first wafer onto a carrier with an adhesive layer, conducts a FEOL process and a BEOL process on the first wafer and the second wafer, forms DBIs on the first wafer and the second wafer, conducts a hybrid bonding process to bond the first wafer and the second wafer by directly bonding DBIs on each of the wafers, conducts a de-bonding process to detach the carrier from the first wafer, and then forms metal interconnections and bonding pads on backside of the detached first wafer so that the wafers are ready for probing test afterwards. By using the temporary carrier 18 to carry the blanket wafer 12 so that the carrier 18 along with the wafer 12 could be undergone FEOL and BEOL processes together before bonding with another wafer, it would be desirable to eliminate the need of using TSVs for bonding wafers for forming stack structures as typically found in conventional art. In the meantime, processes including backside grinding and edge grinding could also be omitted thereby improving yield and lower overall fabrication cost of the process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a first wafer and a second wafer; and
bonding the first wafer onto a carrier by forming an adhesive layer between the carrier and the first wafer.

2. The method of claim 1, further comprising:
conducting a front end of line (FEOL) process and a back end of line (BEOL) process on the first wafer and the second wafer;
forming direct bond interconnects (DBI) on the first wafer and the second wafer;
bonding the first wafer and the second wafer; and
performing a de-bonding process to detach the carrier and the first wafer.

3. The method of claim 2, further comprising performing a hybrid bonding process to bond the first wafer and the second wafer.

4. The method of claim 3, wherein the hybrid bonding process comprises:
reversing the second wafer by facing a front side of the second wafer to a front side of the first wafer; and
bonding the DBI on the second wafer to the DBI on the first wafer.

5. The method of claim 2, further comprising forming the DBI on front sides of the first wafer and the second wafer.

6. The method of claim 2, further comprising:
forming metal interconnections on a backside of the first wafer; and
performing a chip probing test on the metal interconnections.

7. The method of claim 1, further comprising:
thinning the first wafer; and
bonding the first wafer to the carrier.

8. The method of claim 1, wherein a thickness of the first wafer is less than a thickness of the second wafer.

9. The method of claim 1, wherein the carrier and the first wafer comprise same material.

10. The method of claim 1, wherein the carrier and the first wafer comprise different materials.
